(19) United States
(12) Patent Application Publication
(10) Pub. No.: US 2014/0222356 A1
(43) Pub. Date: Aug. 7, 2014

(54) TEMPORAL REFLECTOMETRY SYSTEM AND METHOD FOR UNAMBIGUOUSLY LOCATING AN ELECTRICAL DEFECT IN A CABLE

(71) Applicant: Luca Incarbone, Antony (FR)

(72) Inventor: Luca Incarbone, Antony (FR)

(73) Assignee: COMMISSARIAT A L' ENERGIE ATOMIQUE ET AUX ENERGIES ALTERNATIVES, Paris (FR)

(21) Appl. No.: 14/343,839

(22) PCT Filed: Sep. 5, 2012
(86) PCT No.: PCT/EP2012/067253

§ 371 Date: Mar. 7, 2014

(30) Foreign Application Priority Data
Sep. 9, 2011 (FR) 11 58016

(51) Int. Cl. G01R 31/08; G01R 22/00

(52) U.S. Cl. CPC G01R 31/088; G01R 22/00
USPC 702/59

(57) ABSTRACT

A time domain reflectometry system for the unambiguous location of at least one singularity in a cable, comprises analysis and calculation means for reflectometry signals suited to generating two injection signals from at least one reflectometry signal, two digital-to-analog converters for converting said digital signals into analog signals, two coupling and transmission means for said signals at two distinct points of said cable, at least one analog-to-digital converter for converting the signal reflected by said singularity and received by said coupling and transmission means, said analysis and calculation means furthermore being suited to receiving and analyzing said reflected signal, digitally converted, to produce a time domain reflectogram, said signals being designed such that the signal propagating from one side of said cable is equal to said reflectometry signal and the signal propagating from the other side of said cable is substantially zero.

The present invention relates to the field of time domain reflectometry and notably aims to unambiguously locate a fault in an electric cable.

The invention applies to any type of electric cable, particularly power transmission cables, in fixed or mobile installations. The cables in question may be coaxial, two-wire, parallel-line, twisted-pair or others.

The invention advantageously applies to complex electrical systems made up of a plurality of cables that are interconnected in accordance with a ramified structure. By way of example, the invention may be used for diagnostics for power distribution systems in an airplane.

Known time domain reflectometry systems conventionally operate in accordance with the method below. A controlled signal, for example a pulse signal or else a multicarrier signal, is injected at one end of the cable to be tested. The signal propagates along the cable and is reflected by the singularities that it has.

A singularity in a cable corresponds to a break in the propagation conditions for the signal in this cable. It results most often from a fault that locally modifies the characteristic impedance of the cable, causing a discontinuity in the linear parameters thereof.

The reflected signal is propagated back to the injection point, and is then analyzed by the reflectometry system. The delay between the injected signal and the reflected signal allows a singularity, corresponding to an electrical fault, in the cable to be located.

In some cases, however, it is not possible or desirable to inject the reflectometry signal at one end of the cable. In particular, in a complex and ramified electrical system, the end of the cable to be tested is not always accessible. Furthermore, for onboard applications, for example in an airplane, the implementation of the reflectometry system has to observe compactness constraints and the positioning of this system in the electrical system to be tested can be imposed by the manufacturer. By way of example, when protection systems, such as circuit breakers, are present in the electrical system, it may be advantageous to have the reflectometry system at the same site.

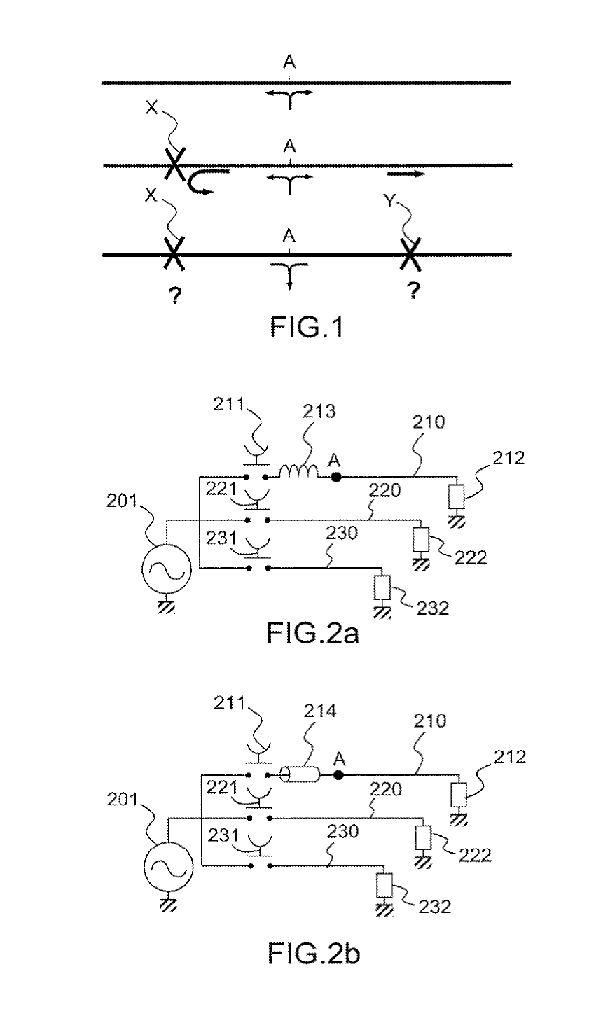

Thus, there are numerous applications for which the time domain reflectometry signal needs to be injected at any point in the cable to be tested and not just at the end thereof. In this case, the location of the fault will not be able to be accomplished unambiguously as illustrated in FIG. 1.

The reason is that the signal injected at any point A in the cable propagates in the two opposite directions. When there is a fault at a point X situated to the left of point A, the analysis of the signal reflected by this fault allows only determination of the distance, as an absolute value, between the fault and injection point A but does not reveal whether this fault is located to the left (point X) or to the right (point Y) of the injection point.

Moreover, when there are electrical faults on both sides of injection point A, the reflected signal received at point A is made up of the superposition of the reflections in the two opposite directions of the cable. The analysis performed is then degraded thereby.

The known solutions allowing unambiguous location of an electrical fault are based on the insertion of additional components on the electrical line to be tested so as to filter the injected signal.

FIG. 2a shows an electrical system to be tested that is made up of a generator 201 connected to three electrical lines 210,220,230, each having a circuit breaker 211,221,231 and being terminated by a load 212,222,232. The electrical line to be tested is the line 210 and the injection point for the reflectometry signal is point A.

A first solution in order to impose a search for faults solely between injection point A and the load 212 involves the introduction of a coil 213 between point A and the circuit breaker 211, said coil allowing the line to be interrupted by acting as a low-pass filter. The injected signal propagating in the direction of the circuit breaker 211 is thus blocked by the coil 213 and is not reflected. Thus, it is possible to impose the test from just one side of the cable at a time.

A drawback of this first solution is its intrusive aspect. It requires the introduction of an additional component in the cable that moreover may have a large dimension, which presents a bulk problem besides.

A second solution, shown schematically in FIG. 2b, involves introducing, instead of the coil 213, a ferromagnetic or ferrite ring 214 in order to produce a low-pass filter in the same way.

However, this solution, although having the advantage of being less intrusive, still has the drawback of requiring the introduction of an additional component and therefore of proposing a very expensive and bulkier solution. Moreover, this solution does not allow total filtering of all the frequency components of the injected signal.

One of the aims of the present invention is to propose a solution that allows unambiguous location of an electrical fault on the basis of access to any point in the cable. The invention does not require the introduction of additional components and is not very bulky.

To this end, the invention relates to a time domain reflectrometry system for the unambiguous location of at least one singularity in a cable, characterized in that it comprises calculation means for reflectometry signals that are suited to generating a first injection signal f_{A}(t) and a second injection signal f_{B}(t) from at least one reflectometry signal s(t), and two coupling and transmission means for said injection signals f_{A}(t),f_{B}(t) at two distinct points (A,B) of said cable, said injection signals f_{A}(t),f_{B}(t) being designed such that the signal propagating from one side of said cable is equal to said reflectometry signal s(t) and the signal propagating from the other side of said cable is substantially zero.

According to a particular aspect of the invention, the first injection signal f_{A}(t) is determined by integrating the reflectometry signal s(t) with respect to time.

According to a particular aspect of the invention, said second injection signal f_{B}(t) is equal to the opposite of said first injection signal f_{A}(t) and is injected into the cable with a predetermined delay in relation to the instant of injection of said first injection signal f_{A}(t).

According to a particular aspect of the invention, said delay is equal to the distance between said injection points (A,B) divided by the speed of propagation of the signal in the cable.

According to a particular aspect of the invention, said injection signals f_{A}(t),f_{B}(t) are generated in digital form f_{A}(n),f_{B}(n), said system furthermore having conversion means for converting said digital signals f_{A}(n),f_{B}(n) into analog signals f_{A}(t),f_{B}(t).

According to a particular aspect of the invention, said digital signals f_{A}(n),f_{B}(n) are designed by resolving the following equation system:

$$\{ \begin{matrix}{f}_{A} ( n + k ) + {f}_{B} ( n ) = 0 \\ {f}_{B} ( n ) + {f}_{A} ( n - k ) = s ( n + k )\end{matrix}$$

where k is equal to the ratio between the propagation time Δt_{AB} for the signal between points A and B and the sampling period Tₑ for said digital signals.

According to a particular aspect of the invention, the distance between the two injection points (A,B) is equal to a multiple or submultiple of the sampling period Tₑ of said digital-to-analog converters that is multiplied by the speed of propagation of the signal in the cable.

In a variant embodiment, the time domain reflectometry system according to the invention furthermore has at least one analog-to-digital converter for converting the signal reflected by said singularity and received by said coupling and transmission means, said calculation means furthermore being suited to receiving and analyzing said reflected signal, digitally converted, to produce a time domain reflectogram.

According to a particular aspect of the invention, said coupling and transmission means are produced by capacitive or inductive effect or by resistive connection.

According to a particular aspect of the invention, said coupling and transmission means are contactless means.

In a variant embodiment, the time domain reflectometry system according to the invention furthermore comprises at least one coupling means for coupling an analog-to-digital converter to a digital-to-analog converter.

According to a particular aspect of the invention, said coupling means are couplers or divider-combiners.

According to a particular aspect of the invention, the calculation means are implemented by a programmable logic circuit or a microcontroller.

In a variant embodiment, the time domain reflectometry system according to the invention furthermore comprises a processing unit suited to controlling said system and to displaying said reflectograms on a man/machine interface.

The invention likewise relates to a method for unambiguous location of at least one singularity in a cable, characterized in that it has at least the following steps:
design of a first injection signal f_{A}(t) and a second injection signal f_{B}(t) from a reflectometry signal s(t) such that the signal propagating from one side of said cable is equal to said reflectometry signal s(t) and the signal propagating from the other side of said cable is substantially zero,
injection of said injection signals f_{A}(t),f_{B}(t), at two distinct points (A,B) of said cable,
acquisition of the signal reflected by at least one singularity in the cable,
production, from the reflected signal, of at least one time domain reflectogram,
determination, from said time domain reflectogram, of the unambiguous position of the singularity on the cable.

According to a particular aspect of the method according to the invention, said first signal f_{A}(t) is determined by integrating the reflectometry signal s(t) with respect to time.

According to a particular aspect of the method according to the invention, said second injection signal f_{B}(t) is equal to the opposite of said first injection signal f_{A}(t) and is injected into the cable with a predetermined delay in relation to the instant of injection of said first injection signal f_{A}(t).

According to a particular aspect of the method according to the invention, said delay is equal to the distance between said injection points (A,B) divided by the speed of propagation of the signal in the cable.

According to a particular aspect of the method according to the invention, said signals f_{A}(n),f_{B}(n) are designed digitally by resolving the following equation system:

$$\{ \begin{matrix}{f}_{A} ( n + k ) + {f}_{B} ( n ) = 0 \\ {f}_{B} ( n ) + {f}_{A} ( n - k ) = s ( n + k )\end{matrix}$$

where k is equal to the ratio between the propagation time Δt_{AB} for the signal between points A and B and the sampling period Tₑ for said digital signals.

According to a particular aspect of the method according to the invention, points A and B are separated by a distance equal to a multiple or submultiple of the sampling period Te for the digital signals f_{A}(n),f_{B}(n).

Other features and advantages of the invention will emerge from the description that follows with reference to the appended drawings, in which:

FIG. 1 shows a diagram illustrating the problem of ambiguous location of an electrical fault in a cable on the basis of the injection of a reflectometry signal at any point in said cable,

FIGS. 2a and 2b show two diagrams of known examples for solving the aforementioned problem,

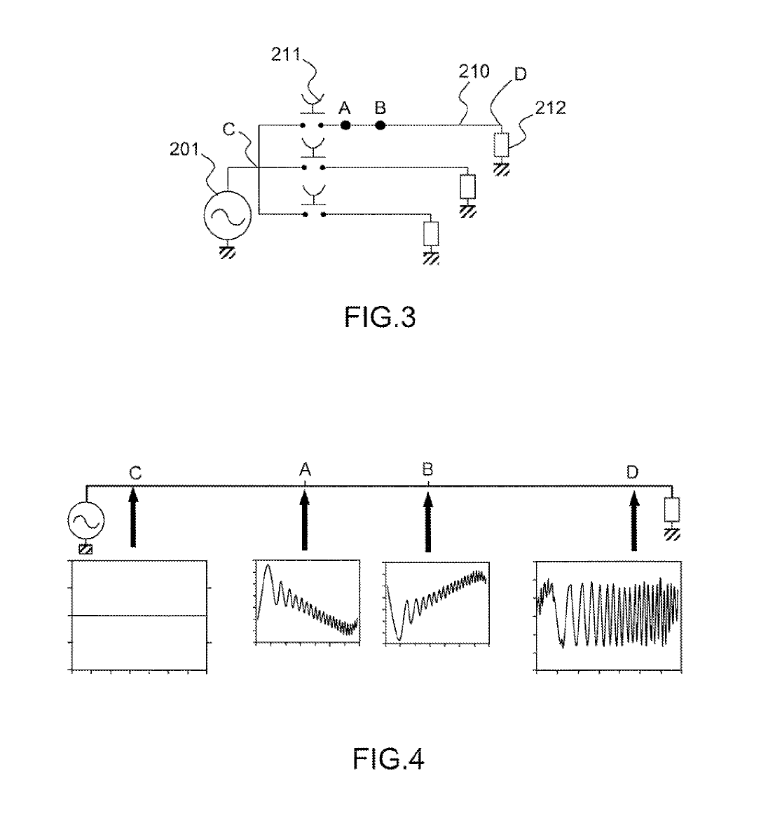

FIG. 3 shows a first diagram illustrating the principle of double injection according to the invention,

FIG. 4 shows a second diagram illustrating the effects obtained by the invention,

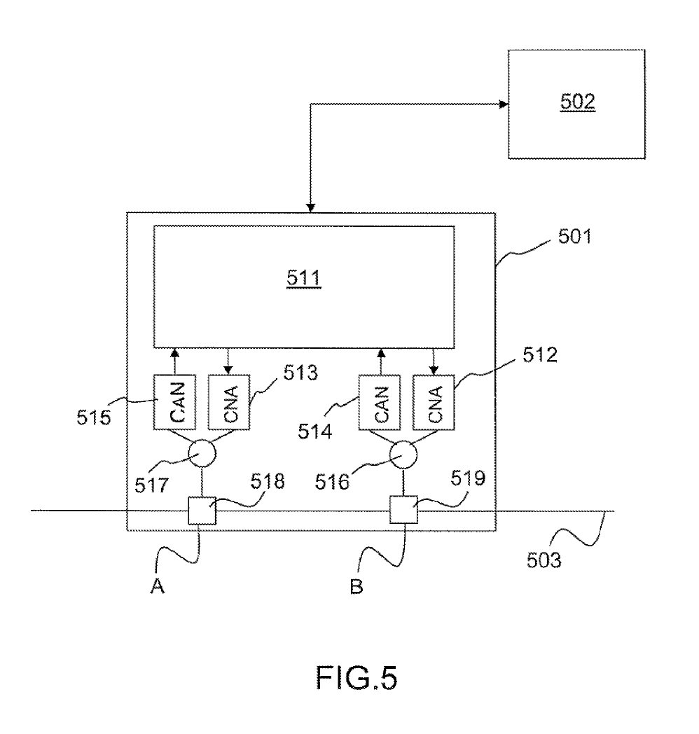

FIG. 5 shows an overview of the reflectometry system according to the invention in a first embodiment of the invention,

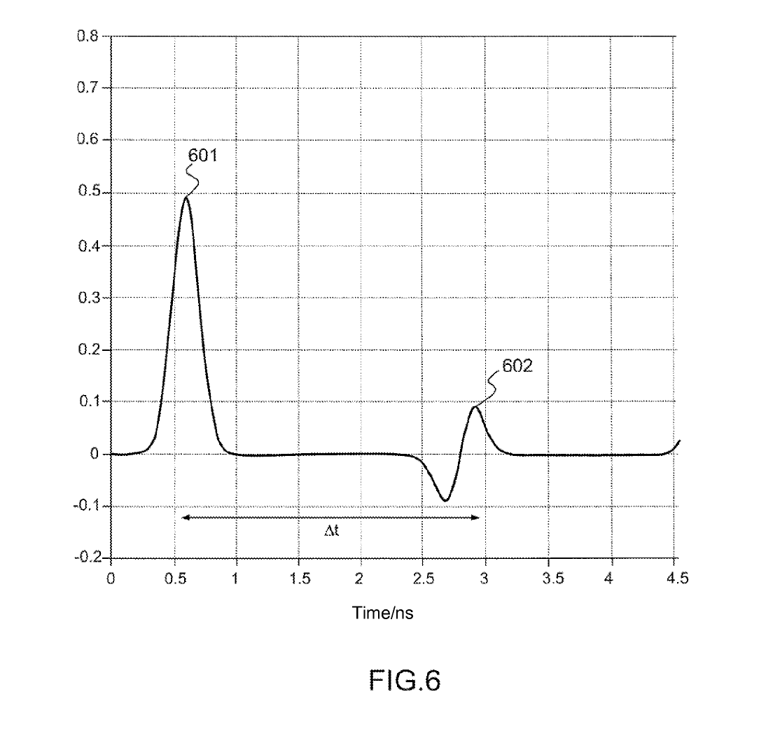

FIG. 6 shows a graph representing an example of a reflectogram obtained by the system according to the invention,

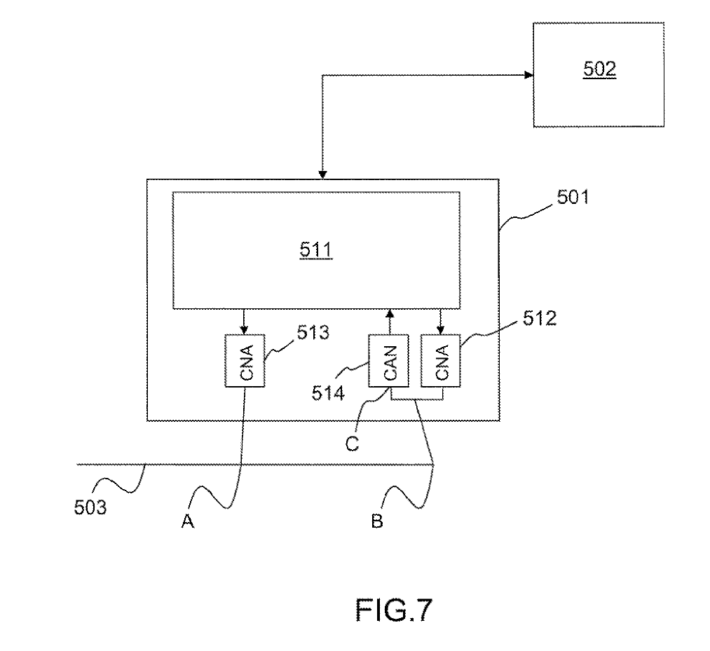

FIG. 7 shows an overview of the reflectometry system according to the invention in a second embodiment of the invention.

FIG. 3 schematically shows the principle on which the invention is based for the same electrical system example that is shown in FIGS. 2a and 2b.

In order to be able to implement unambiguous fault location on the basis of a reflectometry system based on the injection of a reference signal, the reflection of this signal by a singularity that is linked to the fault and the analysis of the reflected signal, it is an aim of the invention to ensure that the injected signal propagates in a single direction rather than in both directions, as would be the case without the invention. By way of example, in the case of the electrical system in FIG. 3, if wishing to test the line 210 solely between the circuit breaker 211 and the load 212, the signal injected at a point close to the circuit breaker 211 must propagate only toward the load 212 and not toward the generator 201.

In order to achieve this aim, the invention notably involves the injection of two signals at two distinct points A and B of the cable. Advantageously, the two injection points A and B are close. The two signals f_{A}(t) and f_{B}(t) are determined such that the signal propagated in one direction is substantially zero and the signal propagated in the other direction is equal to the desired reflectometry signal.

The signal f_{C}(t) propagated toward the generator 201, measured at a point C, satisfies the relationship below, where Δt_{AC} and Δt_{AB} respectively represent the propagation times for the signal between point A and point C, on the one hand, and between point A and point B, on the other:

f_{C}(t)=f_{A}(t−Δt_{AC})+f_{B}(t−Δt_{AC}−Δt_{AB}) (1)

Equally, the signal f_{D}(t) propagated toward the load 212, measured at a point D, satisfies the relationship below, where Δt_{BD} represents the propagation time for the signal between point B and point D.

f_{D}(t)=f_{B}(t−Δt_{BD})+f_{A}(t−Δt_{BD}−Δt_{AB}) (2)

By making the signal propagated from one side of the line, for example toward point C, substantially zero, it is possible to replace f_{C}(t) with 0 in relationship (1) in order to obtain relationship (3):

f_{A}(t−Δt_{AC})+f_{B}(t−Δt_{AC}−Δt_{AB})=0 (3)

Relationship (3) is equivalent to relationship (4) after a change of variable.

f_{A}(t+Δt_{AB})+f_{B}(t)=0 (4)

In the same way, by making the signal propagated toward point D substantially equal to the desired reflectometry signal s(t), it is possible to replace the term f_{D}(t+Δt_{BD}) in relationship (2) with the term s(t+Δt_{AB}), giving relationship (5) after a change of variable:

f_{B}(t)+f_{A}(t−Δt_{AB})=s(t+Δt_{AB}) (5)

Finally, the signals f_{A}(t) and f_{B}(t) must satisfy the following equation system:

$$\{ \begin{matrix}{f}_{A} ( t + Δ {t}_{AB} ) + {f}_{B} ( t ) = 0 \\ {f}_{B} ( t ) + {f}_{A} ( t - Δ {t}_{AB} ) = s ( t + Δ {t}_{AB} )\end{matrix} \qquad ( 6 )$$

Relationship (7) is deduced from system (6):

f_{A}(t+Δt_{AB})−f_{A}(t−Δt_{AB})=−s(t+Δt_{AB}) (7)

Relationship (7) is also equivalent to relationship (8) after a change of variable:

s(t)=−(f_{A}(t)−f_{A}(t−2Δt_{AB})) (8)

On the basis of relationship (8), it can therefore be seen that the signal f_{A}(t) to be injected at point A can be determined in a first approximation by integrating the signal s(t) propagated toward point D, which is no other than the reflectometry signal that is used to detect a singularity on the line 210.

The integration range [−Δt_{AB}, Δt_{AB}] is preferably of duration equal to 2Δt_{AB}, that is to say twice the propagation time for the signal between points A and B.

The signal to be injected at point B can then be determined using relationship (4): f_{B}(t)=−f_{A}(t+Δt_{AB})

The injected signals f_{A}(t) and f_{B}(t) can thus be determined directly in analog form on the basis of relationships (8) and (4) and knowledge of the desired reflectometry signal s(t). The signal f_{A}(t) is thus taken to be equal to the integral, over a time interval of given duration, of the desired reflectometry signal. The signal f_{B}(t) is equal to the opposite of the signal f_{A}(t) and needs to be injected with a temporal offset in relation to the injection of the signal f_{A}(t) that depends on the distance between the two injection points A and B as will be explained subsequently in the digital domain, that is to say in discrete time.

The reason is that the injected signals f_{A}(t) and f_{B}(t) can likewise be generated in digital form at a sampling frequency Fₑ=1/Tₑ. In this case, the following are therefore formulated: t=nTₑ, Δt_{AB}=kTₑ and Δt_{BD}=n₀Tₑ, where n, k and n₀ are three positive integers.

In discrete time, equation system (6) is written as follows:

$$\{ \begin{matrix}{f}_{A} ( n + k ) + {f}_{B} ( n ) = 0 \\ {f}_{B} ( n ) + {f}_{A} ( n - k ) = s ( n + k )\end{matrix} \qquad ( 9 )$$

From system (9), relationship (10) is deduced:

−(f_{A}(n+k)−f_{A}(n−k))=s(n+k) (10)

The signal s(n) propagated toward point D is the reflectometry signal that is used to detect a singularity on the line 210. Thus, recurrence relationship (11) is obtained, allowing the signal f_{A}(n) to be determined:

f_{A}(n+k)=−s(n+k)+f_{A}(n−k) (11)

From this, an expression for the signal f_{A}(n) is deduced by resolving recurrence relationship (10):

$$\begin{matrix}\begin{matrix}{f}_{A} ( n ) = - s ( n ) + {f}_{A} ( n - 2 k ) \\ = s ( n ) + ( - s ( n - 2 k ) + {f}_{A} ( n - 4 k ) ) \\ = s ( n ) + ( - s ( n - 2 k ) + ( - s ( n - 4 k ) + {f}_{A} ( n - 6 k ) ) ) \\ = - {\sum }_{i} s ( n - 2 ik )\end{matrix} & ( 12 )\end{matrix}$$

Relationship (12) conveys integration of the signal s(t) into the digital domain and is equivalent to relationship (13):

$${f}_{A} ( n ) = - {\sum }_{i = 0}^{n} s ( i ) \qquad ( 13 )$$

The signal f_{A}(n) generated for injection at point A is thus determined using relationship (13) and on the basis of the chosen reflectometry signal s(n).

The signal f_{B}(n) generated for injection at point B is then determined using relationships (9) and (13):

f_{B}(n)=−f_{A}(n+k) (14)

The value of k, which, in the continuous time domain, corresponds to the propagation time Δt_{AB} for the signal between injection points A and B, is determined on the basis of the distance d_{AB} between points A and B and the knowledge, by means external to the invention, of the speed of propagation Vₚ of the signal in the cable to be tested. Thus:

Δt_{AB}=d_{AB}/V_{P} and k=Δt_{AB}/Te

In a preferred mode of the invention, the value of k is taken to be equal to 1, the propagation time Δt_{AB} thus being taken to be equal to the sampling period of the signal Tₑ, which means that the means for injecting the signals A and B must be in sync. However, the value of k can likewise be taken to be equal to a multiple or a submultiple of the sampling period Tₑ.

If the sampling frequency is fixed, for example constrained by the digital-to-analog conversion means used, then the distance between injection points A and B is fixed on the basis of the knowledge of the sampling period of the signal Tₑ.

On the other hand, if the sampling frequency can be selected from several available values, then the user of the system according to the invention can choose the most suitable distance d_{AB} for the intended application, notably by taking into account the constraints linked to the bulk or to the dimensions of the reflectometry system.

The signal f_{A}(n) can therefore be determined by means of simple integration of the reflectometry signal s(n) over a given period of time as explained above for the analog case. Although constituting an approximation of the result obtained by application of relationship (13), this continues to be acceptable in terms of performance.

In a particular embodiment of the invention, it is possible to decrease the distance between injection points A and B to a value below Tₑ·V_{P}. This is because in the case in which the clocks of the injection means at points A and B are not in sync, that is to say that the sampling periods of the signals at points A and B are not strictly identical, an offset in the injection between the signal injected at points A and B already exists on account of this asynchronism and may in this case be less than the sampling period Tₑ of one or other of the devices. On the basis of the knowledge of the temporal offset ΔT linked to the fact that the clocks of the injection means at points A and B are out of phase, it is possible to deduce therefrom the distance d_{AB} to be imposed between points A and B by the relationship d_{AB}=ΔT·V_{P}. This particular embodiment of the invention has the advantage of allowing the distance between injection points A and B to be decreased.

FIG. 4 illustrates the effect obtained as a result of the invention. The signals generated and injected at points A and B allow the obtainment of a signal propagated at point C that is substantially zero and a signal propagated at point D that is equal to the desired reflectometry signal s(t). Owing to the invention, the detection of a local change of impedance is possible on the line between points B and D. In order to test the part of the line situated between points A and C, it suffices to invert the signals injected at points A and B.

The method according to the invention thus involves the execution of the following steps. An operator connects the two inputs/outputs of the reflectometry system according to the invention as a shunt for the cable to be tested, to two remote points A and B having a value equal to V_{P}·Δt_{AB}=V_{P}·kTₑ. A reflectometry signal s(t) is chosen that is taken as a basis for calculating the signals to be injected f_{A}(t) and f_{B}(t). The operator chooses the direction of propagation of the desired signal and the signals f_{A}(t) and f_{B}(t) are determined in accordance with this choice. The injection offset between the two signals is determined on the basis of the knowledge of the distance between points A and B or conversely this distance is fixed on the basis of the knowledge of the offset. The signals are then injected into the cable at points A and B and the signal s(t) propagates in the cable until it is reflected by a singularity. The reflected signal is received and recorded by the system and then processed in order to determine the precise location of the singularity by measuring the time difference between the reflected signal and the injected signal.

FIG. 5 schematically shows, in an overview, the reflectometry system in a first embodiment of the invention.

Such a system 501 has at least one electronic component 511 of integrated circuit type, such as a programmable logic circuit, for example of FPGA type, or a microcontroller, two digital-to-analog converters 512,513 for injecting the signals f_{A}(t) and f_{B}(t) into the cable to be tested 503, at least one analog-to-digital converter 514,515 for receiving the signal reflected by the singularities in the cable, at least one coupling device 516,517 between at least one of the two analog-to-digital converters 514,515 and at least one of the two digital-to-analog converters 512,513, and two coupling means 518,519 between two inputs/outputs that the system and the cable to be tested 503 have, said coupling means furthermore being suited to injecting the output signals from the two digital-to-analog converters 512,513 into said cable 503 and to receiving the reflected signal(s).

The system 501 according to the invention is advantageously implemented by an electronic card that holds the digital-to-analog converters 512,513, the analog-to-digital converter(s) 514,515 and the coupling device(s) 516,517. The coupling and injection means 518,519 are connected to two inputs/outputs that the card has.

Moreover, a processing unit 502, such as a computer, personal digital assistant or the like, is used to control the reflectometry system 501 according to the invention and to display the results of the measurements on a man/machine interface.

The electronic component 511 implements firstly the calculation steps that are necessary for generating the injection signals f_{A}(t) and f_{B}(t) on the basis of the reflectometry signal s(t) and secondly an analysis of the reflected signal in order to deduce therefrom a reflectogram that is transmitted to the processing unit 502.

Without departing from the scope of the invention, any device equivalent to a digital-to-analog converter allowing a change from the digital domain to the analog domain is compatible with the invention. Equally, any device allowing a change from the analog domain to the digital domain can replace the analog-to-digital converter.

The injection signals can likewise be generated directly in analog form as explained previously. In this case, the digital-to-analog converters 512,513 are not necessary and the electronic component 511 is replaced by an analog device such as an analog oscilloscope that allows direct generation of the injection signals f_{A}(t) and f_{B}(t) on the basis of a given reflectometry signal s(t). In such a scenario, an additional component needs to be provided in order to introduce a delay that can be configured for the injection of the signal f_{B}(t).

The coupling and transmission means 518,519 can be produced by capacitive or inductive effect or with a resistive connection. They can be implemented by physical connection means. By way of example, if the system according to the invention is integrated with a protective device, of circuit breaker type, that is already present on the electrical system to be tested, physical connectors allowing the injection of signals into the cable are provided. They can likewise be implemented by contactless injection means, for example by using a metal cylinder, the internal diameter of which is substantially equal to the external diameter of the cable and that produces an effect of capacitive coupling to the cable.

The coupling means 516,517 between the converters 512 and 514, on the one hand, and 513 and 515, on the other, can be produced by a simple coupler that provides a link between each pair of converters and each input/output of the system. In this case, the output signal from the digital-to-analog converters 512,513 that is ready to be injected, via the two outputs of the system 501, into the cable to be tested is likewise transmitted, via the couplers 516,517, to the analog-to-digital converters 514,515 that have the task of receiving the signal reflected by the singularities in the cable. In this case, the reflectogram obtained following processing of the signal received at an input/output of the system will have both a peak relating to the injected signal and another peak relating to the reflected signal. An example of such a reflectogram is shown in FIG. 6.

The reflectogram in FIG. 6 has a first peak 601 that corresponds to the injection point of the signal, which in this case is a time domain pulse. The second peak 602 corresponds to a singularity in the cable following an electrical fault. The measurement of the temporal offset Δt between the second peak 602 and the first peak 601 allows the distance between the injection point for the signal and the electrical fault to be deduced therefrom.

A drawback is that the presence of the injected signal on the reflectogram can adversely affect the performance of measurement of the distance between the electrical fault detected on the cable and the injection point for the following reason. The further away the electrical fault from the injection point, the more the reflected signal received by the system will be attenuated and the more the precision of the measurement of the delay between injected signal and reflected signal decreases. The precision is decreased still further when the reflectogram has the two signals, because after normalization the relative amplitude of the reflected signal in relation to that of the injected signal is small.

For these reasons, it may be advantageous to use a divider-combiner as coupling means 516,517, said divider-combiner allowing firstly the output signal from the digital-to-analog converter 512 to be directed to the output of the system and secondly the reflected signal received at an input of the system to be directed to the analog-to-digital converter 514. In this way, the reflectogram has only the information that is useful for locating the electrical fault.

In a variant embodiment of the invention, which is not shown in FIG. 5, a single analog-to-digital converter 514,515 is necessary in order to acquire the reflected signal. Advantageously, the analog-to-digital converter 514,515 is coupled to the digital-to-analog converter 512,513 connected to the injection point closest to the side of the cable to be tested.

FIG. 7 schematically shows another variant of implementation of the method and the system according to the invention, in which only an analog-to-digital converter 514 is necessary.

In a case in which additional coupling and injection means 518,519 are not desired and one end B of the cable to be tested is accessible, the invention likewise allows the use of a divider-combiner to be eliminated by correcting the drawback, explained above, of using a single coupler to connect the analog-to-digital converter 514 to one of the digital-to-analog converters 512.

To accomplish this, the converters 512,514 connected to one another by means of a single coupler are connected, via an input/output of the system according to the invention, to the end B of the cable to be tested. The second digital-to-analog converter 513 is connected, by means of resistive connection, to a second point A of the cable that is remote from point B. The distance between the two points is determined, as already explained previously, on the basis of the knowledge of the speed of propagation of the signal in the cable and the sampling period of the converters.

In consideration of the line connecting the input point C for the analog-to-digital converter 514 to point A and passing through point B and in application of the method according to the invention, the injection of the signals f_{A}(t) and f_{B}(t) at points A and B allows the propagation of the signal toward point C to be eliminated. Thus, the signal reflected and then received by the system at the input C has only the information that is necessary for locating the electrical fault in the cable 503.

The main advantage of the invention is that it does not require the introduction of additional components on the cable to be tested. The features of the cable are thus not modified, including the passband of said cable, in so far as the output impedance of the diagnostic system is transparent to the frequencies used in the intended application. The disadvantage of adding components is that they can require bulky dimensions, which are necessary in order to guarantee compliance with the various standards used, for example in the field of onboard electrical systems in an airplane.

1. A time domain reflectrometry system for the unambiguous location of at least one singularity in a cable, comprising: calculation means for reflectometry signals that are suited to generating a first injection signal f_{A}(t) and a second injection signal f_{B}(t) from at least one reflectometry signal s(t), and two coupling and transmission means for said injection signals f_{A}(t),f_{B}(t) at two distinct points (A,B) of said cable, said injection signals f_{A}(t),f_{B}(t) being designed such that the signal propagating from one side of said cable is equal to said reflectometry signal s(t) and the signal propagating from the other side of said cable is substantially zero.

2. The time domain reflectometry system of claim 1, wherein said first injection signal f_{A}(t) is determined by integrating the reflectometry signal s(t) with respect to time.

3. The time domain reflectometry system of claim 2, in which said second injection signal f_{B}(t) is equal to the opposite of said first injection signal f_{A}(t) and is injected into the cable with a predetermined delay in relation to the instant of injection of said first injection signal f_{A}(t).

4. The time domain reflectometry system of claim 3, in which said delay is equal to the distance between said injection points (A,B) divided by the speed of propagation of the signal in the cable.

5. The time domain reflectometry system of claim 1, in which said injection signals f_{A}(t),f_{B}(t) are generated in digital form f_{A}(n),f_{B}(n), said system furthermore having conversion means for converting said digital signals f_{A}(n),f_{B}(n) into analog signals f_{A}(t),f_{B}(t).

6. The time domain reflectometry system as claimed in claim 5, wherein said digital signals f_{A}(n),f_{B}(n) are designed by resolving the following equation system:
$$\{ \begin{matrix}{f}_{A} ( n + k ) + {f}_{B} ( n ) = 0 \\ {f}_{B} ( n ) + {f}_{A} ( n - k ) = s ( n + k )\end{matrix}$$
where k is equal to the ratio between the propagation time Δt_{AB} for the signal between points A and B and the sampling period Tₑ for said digital signals.

7. The time domain reflectometry system of claim 5, wherein the distance between the two injection points (A,B) is equal to a multiple or submultiple of the sampling period Tₑ of said digital-to-analog converters that is multiplied by the speed of propagation of the signal in the cable.

8. The time domain reflectometry system of claim 1, furthermore having at least one analog-to-digital converter for converting the signal reflected by said singularity and received by said coupling and transmission means, said calculation means furthermore being suited to receiving and analyzing said reflected signal, digitally converted, to produce a time domain reflectogram.

9. The time domain reflectometry system of claim 1, wherein said coupling and transmission means are produced by capacitive or inductive effect or by resistive connection.

10. The time domain reflectometry system of claim 1, wherein said coupling and transmission means are contactless means.

11. The time domain reflectometry system of claim 1, comprising at least one coupling means for coupling an analog-to-digital converter to a digital-to-analog converter.

12. The time domain reflectometry system of claim 11, wherein said coupling means are couplers or divider-combiners.

13. The time domain reflectometry system of claim 1, wherein the calculation means are implemented by a programmable logic circuit or a microcontroller.

14. The time domain reflectometry system of claim 1, comprising a processing unit suited to controlling said system and to displaying said reflectograms on a man/machine interface.

15. A method for unambiguous location of at least one singularity in a cable, comprising at least the following steps:
design of a first injection signal f_{A}(t) and a second injection signal f_{B}(t) from a reflectometry signal s(t) such that the signal propagating from one side of said cable is equal to said reflectometry signal s(t) and the signal propagating from the other side of said cable is substantially zero,
injection of said injection signals f_{A}(t),f_{B}(t), at two distinct points (A,B) of said cable,
acquisition of the signal reflected by at least one singularity in the cable,
production, from the reflected signal, of at least one time domain reflectogram,
determination, from said time domain reflectogram, of the unambiguous position of the singularity on the cable.

16. The location method of claim 15, in which said first signal f_{A}(t) is determined by integrating the reflectometry signal s(t) with respect to time.

17. The location method of claim 16, in which said second injection signal f_{B}(t) is equal to the opposite of said first injection signal f_{A}(t) and is injected into the cable with a predetermined delay in relation to the instant of injection of said first injection signal f_{A}(t).

18. The location method of claim 17, in which said delay is equal to the distance between said injection points (A,B) divided by the speed of propagation of the signal in the cable.

19. The location method of claim 15, wherein said signals f_{A}(n),f_{B}(n) are designed digitally by resolving the following equation system:
$$\{ \begin{matrix}{f}_{A} ( n + k ) + {f}_{B} ( n ) = 0 \\ {f}_{B} ( n ) + {f}_{A} ( n - k ) = s ( n + k )\end{matrix}$$
where k is equal to the ratio between the propagation time Δt_{AB} for the signal between points A and B and the sampling period Tₑ for said digital signals.

20. The location method of claim 19, wherein points A and B are separated by a distance equal to a multiple or submultiple of the sampling period Te for the digital signals f_{A}(n),f_{B}(n).
